(19) United States
(12) Patent Application Publication
(10) Pub. No.: US 2026/0343681 A1
(43) Pub. Date: Oct. 29, 2026

(54) LAMP AND WINDOW CONFIGURATIONS FOR SUBSTRATE PROCESSING CHAMBERS

(71) Applicant: Applied Materials, Inc., Santa Clara, CA (US)

(72) Inventors: Venkateswaran SUBBARAMAN, San Jose, CA (US); Raja Murali DHAMODHARAN, Madurai (IN)

(21) Appl. No.: 19/110,211

(22) PCT Filed: Sep. 28, 2023
(86) PCT No.: PCT/US2023/034008

§ 371 Date: Mar. 10, 2025

Related U.S. Application Data
(60) Provisional application No. 63/412,816, filed on Oct. 3, 2022.

(51) Int. Cl. H05B 3/00; C30B 25/10; H05B 3/06; H05B 3/42; H05B 3/84

(52) U.S. Cl. CPC H05B 3/0047; C30B 25/105; H05B 3/06; H05B 3/42; H05B 3/84; H05B 2203/032

(57) ABSTRACT

The present disclosure relates to heat sources (e.g., lamps) and windows for processing chambers, and related methods. In one or more embodiments, a lamp applicable for use in semiconductor manufacturing includes a bulb tube extending along at least a segment of an arcuate profile. The bulb tube defines an arcuate central opening. The lamp includes a filament positioned in the arcuate central opening. The filament extends along at least the segment of the arcuate profile. The lamp includes a reflective coating formed on a first portion of an outer face of the bulb tube.

### BACKGROUND

### Field

The present disclosure relates to heat sources (e.g., lamps) and windows for processing chambers, such as those suitable for semiconductor processing, and related methods.

### Description of the Related Art

Semiconductor substrates are processed for a wide variety of applications, including the fabrication of integrated devices and microdevices.

However, thermal processing can be limited with respect to thermal efficiency, temperature uniformity, product lifespans, yield and throughput, chamber costs, and operating costs. As an example, heating devices can have relatively short operating lifespans. As another example, temperatures on substrates can be non-uniform during heating, such as by the outer edge of a substrate being cooler than a center of the substrate. As a further example, a relatively small percentage (e.g., 10%) of heat generated in a chamber may actually be absorbed by a substrate.

Therefore, a need exists for improved chambers and related apparatus and methods that facilitate increased yield and throughput, increased thermal efficiency, more uniformity during processing, and reduced costs.

### SUMMARY

The present disclosure relates to heat sources (e.g., lamps) and windows for processing chambers, and related methods.

In one or more embodiments, a lamp applicable for use in semiconductor manufacturing includes a bulb tube extending along at least a segment of an arcuate profile. The bulb tube defines an arcuate central opening. The lamp includes a filament positioned in the arcuate central opening. The filament extends along at least the segment of the arcuate profile. The lamp includes a reflective coating formed on a first portion of an outer face of the bulb tube.

In one or more embodiments, a window applicable for use in semiconductor manufacturing include an outer section, and an inner section disposed inwardly of the outer section. The inner section includes a first outer face, a second outer face opposing the first outer face, and one or more grooves formed in the first outer face.

In one or more embodiments, a processing chamber applicable for use in semiconductor manufacturing includes an internal volume, and a substrate support disposed in the internal volume. The substrate support comprising a support face. The processing chamber includes a window at least partially defining a processing volume of the internal volume. The window includes an outer section, and an inner section disposed inwardly of the outer section and having a radial center and a radial outer edge that interfaces with the outer section. The inner section includes a first outer face facing away from the support face, and a second outer face opposing the first outer face. The second outer face faces the support face. The inner section includes one or more grooves formed in the first outer face. The processing chamber includes a plurality of lamps received in the one or more grooves of the window. The plurality of lamps are supported by the inner section such that a distance between the lamps and the support face has a gradient that transitions toward the support face in a direction from the radial center to the radial outer edge.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic side cross-sectional view of a processing chamber, according to one or more embodiments.

FIG. 2 is a schematic side cross-sectional view of the plurality of lamps and the window shown in FIG. 1, according to one or more embodiments.

FIG. 3 is a schematic top view of the plurality of lamps and the window shown in FIG. 2, according to one or more embodiments.

FIG. 4 is an enlarged view of the plurality of lamps and the window shown in FIG. 2, according to one or more embodiments.

FIG. 5 is a schematic perspective view of the window shown in FIGS. 1-4 and a plurality of lamps, according to one or more embodiments.

FIG. 6 is a schematic top view of the plurality of lamps and the window shown in FIG. 5, according to one or more embodiments.

FIG. 7 is a schematic perspective view of a window and a plurality of lamps, according to one or more embodiments.

FIG. 8 is a schematic top view of the plurality of lamps and the window shown in FIG. 7, according to one or more embodiments.

FIG. 9 is a schematic side cross-sectional view of the plurality of lamps shown in FIGS. 1-4 and a window, according to one or more embodiments.

FIG. 10 is a schematic top view of the plurality of lamps and the window shown in FIG. 9, according to one or more embodiments.

FIG. 11 is a schematic perspective view of the plurality of lamps and the window shown in FIG. 9, according to one or more embodiments.

FIG. 12 is a schematic cross-sectional view of the plurality of lamps and the window shown in FIG. 11, according to one or more embodiments.

FIG. 13 is a schematic side cross-sectional view of the plurality of lamps shown in FIGS. 9-12 and a window, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to heat sources (e.g., lamps) and windows for processing chambers, and related methods.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links.

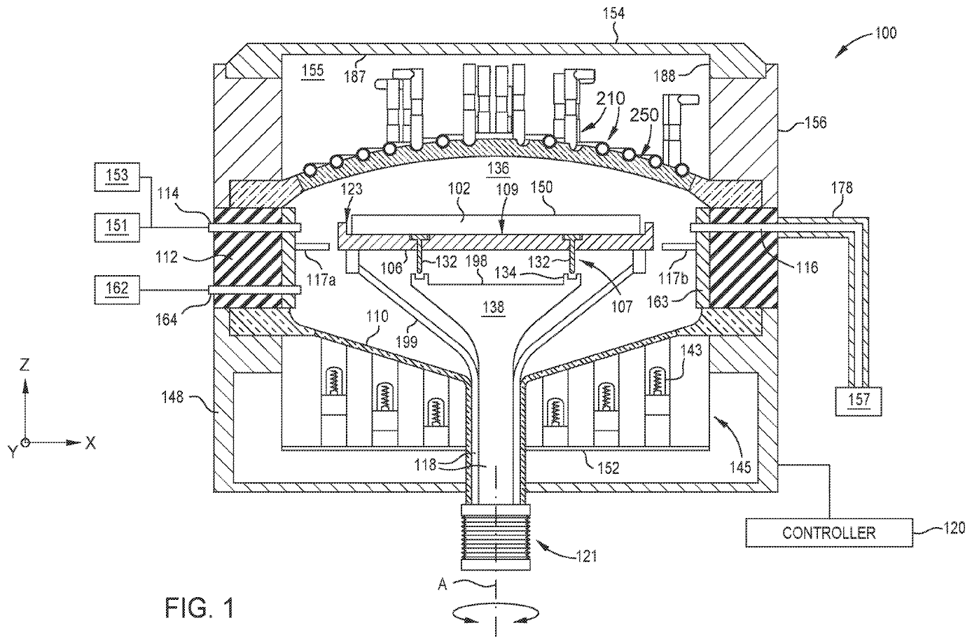

FIG. 1 is a schematic side cross-sectional view of a processing chamber 100, according to one or more embodiments. The processing chamber 100 is a deposition chamber. In one embodiment, which can be combined with other embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, a flow module 112 disposed between the upper body 156 and the lower body 148. In one or more embodiments, the upper body 156 includes an upper clamp ring and the lower body 148 includes a lower clamp ring. The upper body 156, the flow module 112, and the lower body 148 form a chamber body. Disposed within the chamber body is a substrate support 106, an upper window 250 (such as an upper dome), a lower window 110 (such as a lower dome), a plurality of upper lamps 210, and a plurality of lower lamps 143. As shown, a controller 120 is in communication with the processing chamber 100 and is used to control processes and methods, such as the operations of the methods described herein. The substrate support 106 has a support face 109 that supports the substrate 102.

The substrate support 106 is disposed between the upper window 250 and the lower window 110. The substrate support 106 includes a support face 123 that supports the substrate 102. The plurality of upper lamps 210 are disposed between the upper window and a lid 154. The plurality of upper lamps 210 form a portion of the upper lamp module 155. The lid 154 may include a plurality of sensors (not shown) disposed therein for measuring the temperature within the processing chamber 100. In one or more embodiments, a reflective coating is formed on one or more inner surfaces 187, 188 of the lid 154. The reflective coating can be similar to or the same as one or more of the reflective coating 219 and/or the reflective coating of the reflective plate 280 described below. The plurality of lower lamps 143 are disposed between the lower window 110 and a floor 152. The plurality of lower lamps 143 form a portion of a lower lamp module 145. The upper window 250 is an upper dome and is formed of an energy transmissive material, such as quartz. The lower window 110 is a lower dome and is formed of an energy transmissive material, such as quartz.

A process volume 136 and a purge volume 138 are formed between the upper window 250 and the lower window 110. The process volume 136 and the purge volume 138 are part of an internal volume defined at least partially by the upper window 250, the lower window 110, and the one or more liners 163.

The internal volume has the substrate support 106 disposed therein. The substrate support 106 includes a top surface on which the substrate 102 is disposed. The processing chamber includes a first support frame 198 and a second support frame 199 disposed at least partially about the first support frame 198. The second support frame 199 includes arms coupled to the substrate support 106 such that lifting and lowering the second support frame 199 lifts and lowers the substrate support 106. A plurality of lift pins 132 are suspended from the substrate support 106. Lowering of the substrate support 106 initiates contact of the lift pins 132 with arms of the first support frame 198. Continued lowering of the substrate support 106 initiates contact of the lift pins 132 with the substrate 102 such that the lift pins 132 raise the substrate 102. A bottom region 205 of the chamber sides 201a, 201b is defined between the chamber body bottom 234 and the first and second pedestals 254a, 254b. A stem 118 (such as a shaft) of each support frame 198, 199 extends through a bottom of the lower body 148.

The substrate support 106 is attached to the stem 118 of the second support frame 199 through the arms. The stem 118 of each support frame 198, 199 is connected to a motion assembly 121. The motion assembly 121 includes one or more actuators and/or adjustment devices that provide movement and/or adjustment for the support frames 198, 199 within the processing volume 136. The substrate support 106 may include lift pin holes 107 disposed therein. The lift pin holes 107 are each sized to accommodate a respective lift pin 132 of the lift pins 132 for lifting of the substrate 102 from the substrate support 106 before or after a deposition process is performed. The lift pins 132 may rest on lift pin stops 134 when the substrate support 106 is lowered from a process position to a transfer position. In the implementation shown in FIG. 1, the lift pin stops 134 are part of the arms of the first support frame 198.

The flow module 112 includes a plurality of gas inlets 114, a plurality of purge gas inlets 164, and one or more gas exhaust outlets 116. The plurality of gas inlets 114 and the plurality of purge gas inlets 164 are disposed on the opposite side of the flow module 112 from the one or more gas exhaust outlets 116. One or more flow guides 117a, 117b are disposed below the plurality of gas inlets 114 and the one or more gas exhaust outlets 116. The one or more flow guides 117a, 117b are disposed above the purge gas inlets 164. One or more liners 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a gas parallel to the top surface 150 of a substrate 102 disposed within the process volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (Cl). In one embodiment, which can be combined with other embodiments, the one or more process gases include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 to the exhaust pump 157. The exhaust system 178 can assist in the controlled deposition of a layer on the substrate 102. The exhaust system 178 is disposed on an opposite side of the processing chamber 100 relative to the flow module 112.

The controller 120 includes a central processing unit (CPU), a memory containing instructions, and support circuits for the CPU. The controller 120 controls various items directly, or via other computers and/or controllers. In one or more embodiments, the controller 120 is communicatively coupled to dedicated controllers, and the controller 120 functions as a central controller.

The controller 120 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 120 are coupled to the CPU for supporting the CPU (a processor). The support circuits include cache, power supplies, clock circuits, input/output circuitry and subsystems, and the like. Operational parameters (such as heating powers applied to individual heat sources (e.g., lamps), pressure for process gas, a flow rate for process gas, and/or a rotational position of the substrate support 106) and operations are stored in the memory as a software routine that is executed or invoked to turn the controller 120 into a specific purpose controller to control the operations of the various chambers/modules described herein. The controller 120 is configured to conduct any of the operations described herein. The instructions stored on the memory, when executed, cause one or more of the operations described herein to be conducted.

The various operations described herein can be conducted automatically using the controller 120, or can be conducted automatically or manually with certain operations conducted by a user.

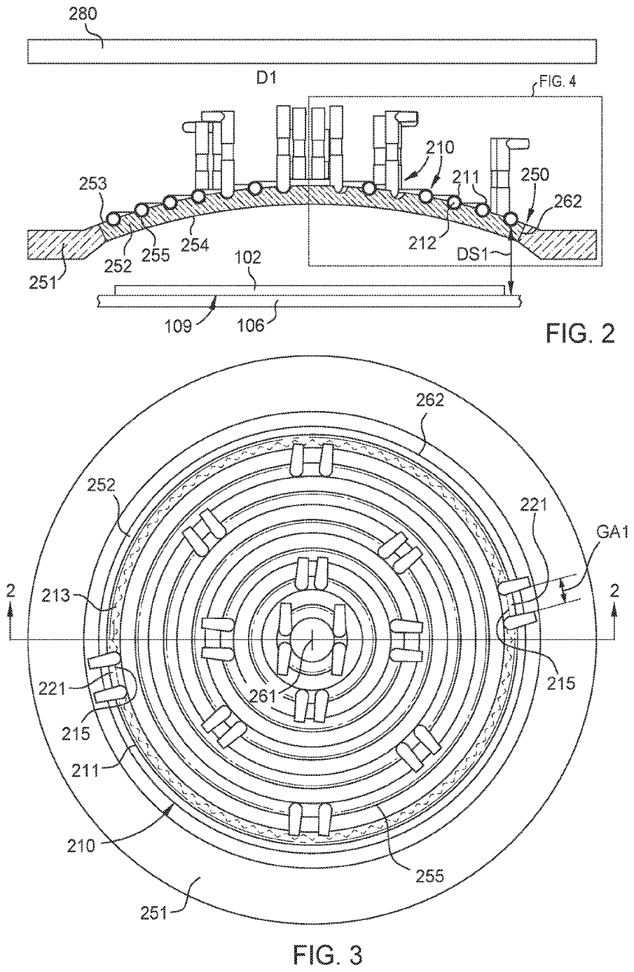

FIG. 2 is a schematic side cross-sectional view of the plurality of lamps 210 and the window 250 shown in FIG. 1, according to one or more embodiments.

FIG. 3 is a schematic top view of the plurality of lamps 210 and the window 250 shown in FIG. 2, according to one or more embodiments.

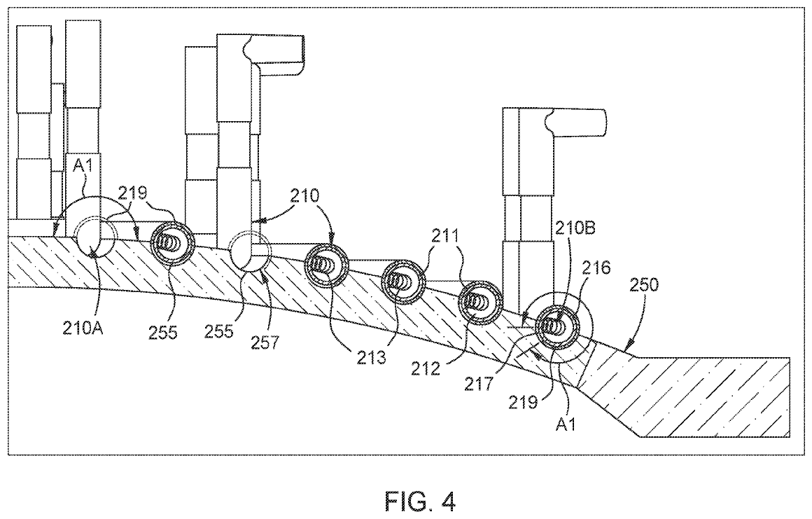

FIG. 4 is an enlarged view of the plurality of lamps 210 and the window 250 shown in FIG. 2, according to one or more embodiments.

Each lamp 210 includes a bulb tube 211 extending along at least a segment of an arcuate profile 215. In one or more embodiments, the arcuate profile 215 is a circular profile. In one or more embodiments, the bulb tubes 211 are cylindrical. In one or more embodiments, cross sections of the bulb tubes 211 are arcuate (e.g., circular) in shape. The present disclosure contemplates that other shapes (e.g., rectangular shapes) may be used for the cross sections of the bulb tubes 211.

Each bulb tube 211 defines an arcuate central opening 212. Each lamp 210 includes a filament 213 positioned in the arcuate central opening 212, and the filament 213 extends along the segment of the arcuate profile. Each lamp 210 includes a reflective coating 219 formed on a first portion 216 of an outer face of the bulb tube 211. The reflective coating 219 is formed over the first portion 216 such that a second portion 217 of the outer face is uncoated. The reflective coating 219 has a reflectivity that is 0.8 or higher. In one or more embodiments, the reflective coating 219 includes one or more of: gold (Au), silver (Ag), alumina (Al₂O₃), and/or one or more other ceramics. Other materials are contemplated for the reflective coating 219. For each lamp 210, the reflective coating 219 is formed over the first portion 216 at a coating angle A1 about the bulb tube 211. The coating angle A1 is at least 180 degrees. For at least one of the lamps 210, the coating angle A1 is at least 210 degrees, such as 240 degrees or higher. For a radially innermost lamp 210A, the coating angle A1 is about 180 degrees. For a radially outermost lamp 210B, the coating angle A1 is about 300 degrees. The coating angle A1 increases the farther radially outward a lamp 210 is disposed.

The reflective coating 219 facilitates directing light from the lamps 210 towards the substrate 102 being processed, reducing the light lost to other chamber components, which facilitates heating efficiency and reduced power consumption.

In the implementation shown in FIG. 3, seven radial locations (relative to a center of the window 250) are shown, which each radial location having a respective arcuate profile 215. For each radial location a plurality bulb tubes 211 (two are shown for each radial location in FIG. 3) are disposed along the respective arcuate profile such that angular gaps 221 are defined between terminal ends of adjacent bulb tubes 211. Two angular gaps 221 are shown at each radial location in FIG. 3. The angular gaps 221 of each radial location each have a gap angle GA1 that is less than 15 degrees. In one or more embodiments, the gap angle GA1 is 10 degrees or less. In one or more embodiments, the gap angles GA1 of the angular gaps 221 can be different from each other across the lamps 210. The present disclosure contemplates other values for the gap angle GA1.

The window 250 includes an outer section 251 and an inner section 252 disposed inwardly of the outer section 251. The inner section 252 includes a first outer face 253, a second outer face 254 opposing the first outer face 253, and one or more grooves 255 formed in the first outer face 253. A plurality of grooves 255 (seven) are shown in the implementation of FIGS. 2-4, and a groove 255 is formed at each of the seven radial locations. The plurality of grooves 255 are disposed in a concentric arrangement with respect to each other in the implementation shown in FIGS. 2-4. The lamps 210 are received in the grooves 255. Each lamp 210 of the plurality of lamps 210 is disposed in an arcuate section 257 of a respective groove 255 of the plurality of grooves 255. In the implementation shown in FIGS. 2-4, a plurality of lamps 210 are disposed in each groove 255 (two lamps 210 are shown in each groove 255 in FIGS. 1-4. The present disclosure contemplates that a different number (such as eight or more, or six or less) of radial locations can be used, one or more grooves 255 can be disposed at each radial location, and one or more lamps 210 can be disposed in each groove 255.

The inner section 252 has a radial center 261 and a radial outer edge 262 that interfaces with the outer section 251. As shown in FIGS. 2 and 4, the first outer face 253 has a gradient that transitions toward the second outer face 254 in a direction D1 from the radial center 261 to the radial outer edge 262. In one or more embodiments, the inner section 252 is transparent and the outer section 251 is opaque. The inner section 252 is configured to pass 95% or more of infrared light and the outer section 251 is configured to absorb infrared light.

The bulb tubes 211 of the lamps are transparent configured to pass 95% or more of infrared light. Each of the bulb tubes 211, the inner section 252, and/or the outer section 251 can be formed of one or more of quartz (such as clear quartz or opaque quartz), silicon carbide (SiC), and/or graphite coated with SiC and/or opaque quartz. In one or more embodiments, the inner section 252 is formed of a transparent material (such as transparent quartz) and the outer section 251 is formed of an opaque material (such as opaque quartz, SiC, and/or graphite coated with SiC and/or opaque quartz).

As discussed above, the window 250 and the lamps 210 can be disposed in a processing chamber, such as the processing chamber 100 shown in FIG. 1. When disposed in the processing chamber 100, the window 250 at least partially defines the processing volume 136. The first outer face 253 faces away from the support face 109 and the second outer face 254 faces the support face 109. The lamps 210 are disposed in the grooves 255 and supported by the inner section 252 such that a distance DS1 between the lamps 210 and the support face 109 has a gradient that transitions toward the support face 109 in the direction D1 from the radial center 261 to the radial outer edge 262 of the inner section 252. In one or more embodiments, the distance DS1 is less than 5.0 inches for each and every one of the lamps 210. The distance DS1 facilitates more uniform heating, less power consumption, and less heating losses due to chamber components absorbing light. In one or more embodiments, the distance DS1 is within a range of 2.0 inches to 3.0 inches for the radially innermost lamp 210A, and the distance DS1 is about 2.0 inches for the radially outermost lamp 210B. The distance DS1 is smaller the farther each lamp 210 is from the radial center 261 to facilitate center-to-edge substrate temperature uniformity and deposition uniformity.

In one or more embodiments, the inner section 252 has a uniform thickness between the radial center 261 and the radial outer edge 262, save for the portions aligned with the grooves 255. The uniform thickness facilitates reduced or eliminated effects from thermal stresses during processing.

A reflective plate 280 can be positioned above the window 250. In one or more embodiments, the reflective plate 280 is part of the lid 154, or is positioned between the lid 154 and the window 250. In one or more embodiments, the reflective plate 280 is formed of aluminum (Al), and or is coated with a reflective coating having a reflectivity that is 0.8 or higher. In one or more embodiments, the reflective coating includes one or more of: gold (Au), silver (Ag), alumina (Al₂O₃), and/or one or more other ceramics. Other materials are contemplated for the reflective coating of the reflective plate 280. The present disclosure contemplates that the reflective plate 280 can be omitted.

In one or more embodiments, a first power is applied to an innermost set of one or more lamps 210 at an innermost radial location (e.g., closest to the radial center 261), and a second power is applied to an outermost set of one or more lamps 210 at an outermost radial location (e.g., closest to the radial outer edge 262). The second power is higher than the first power. In one or more embodiments, the second power is a ratio of the first power, and the ratio is at least 1.5, such as about 2.0. In one or more embodiments, the first power is less than 1.3 kW, such as about 1.0 kW. In one or more embodiments, the second power is within a range of 1.8 kW to 2.2 kW, such as about 2.0 kW.

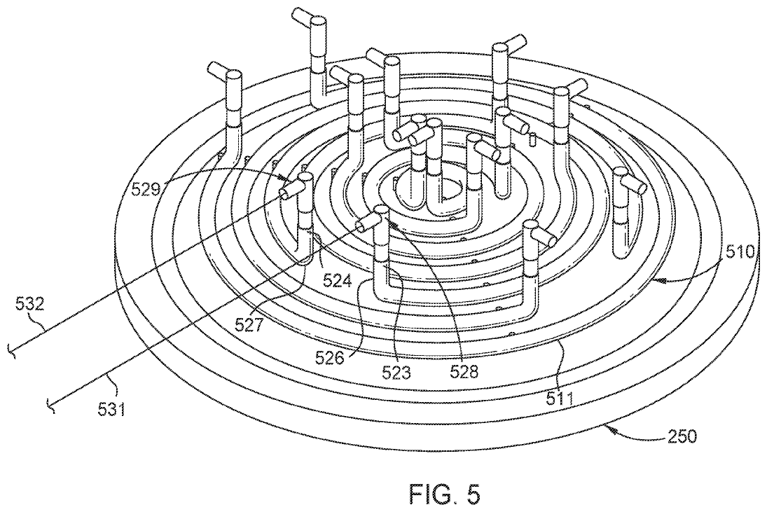

FIG. 5 is a schematic perspective view of the window 250 shown in FIGS. 1-4 and a plurality of lamps 510, according to one or more embodiments.

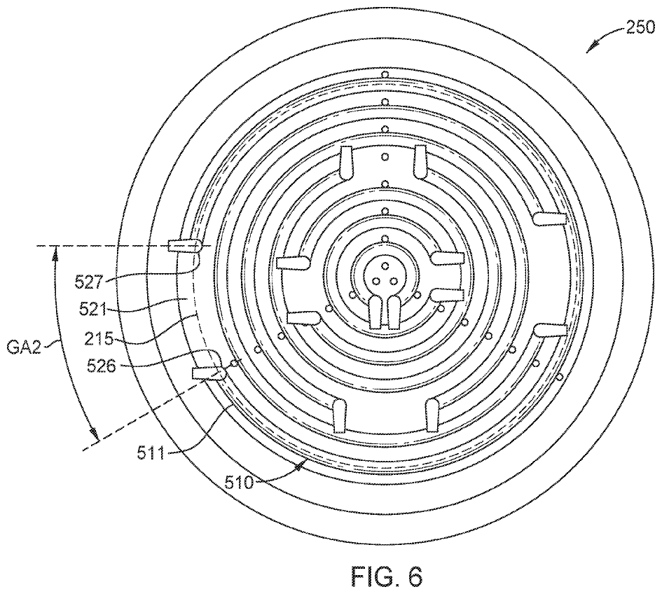

FIG. 6 is a schematic top view of the plurality of lamps 510 and the window 250 shown in FIG. 5, according to one or more embodiments.

The lamps 510 are similar to the lamps 210 shown in FIGS. 1-4 and include one or more of the aspects, features, components, operations, and/or operations thereof.

Each lamp 510 includes a first extension tube 523 disposed adjacent a first terminal end 526 of a bulb tube 511 and extending to intersect the bulb tube 511. Each lamp 510 includes a second extension tube 524 disposed adjacent a second terminal end 527 of the bulb tube 511 and extending to intersect the bulb tube 511. Each lamp 510 includes a first electrical connector 528 coupled to the first extension tube 523, and a second electrical connector 529 coupled to the second extension tube 524. The first electrical connector 528 is configured to couple to a supply line 531, and the second electrical connector 529 configured to couple a ground line 532. In one or more embodiments, the bulb tubes 511 are cylindrical. In one or more embodiments, cross sections of the bulb tubes 511 are arcuate (e.g., circular) in shape. The present disclosure contemplates that other shapes (e.g., rectangular shapes) may be used for the cross sections of the bulb tubes 511.

In the implementation shown in FIG. 6, the bulb tube 511 extends along at least part of a segment of the arcuate profile 215 of each radial location to define an angular gap 521 between the first terminal end 526 and the second terminal end 527 of the bulb tube 511. The angular gap 521 of each radial location has a gap angle GA2 that is less than 45 degrees.

In the implementation shown in FIGS. 5 and 6, a single lamp 510 is disposed in each groove 255 of the window 250.

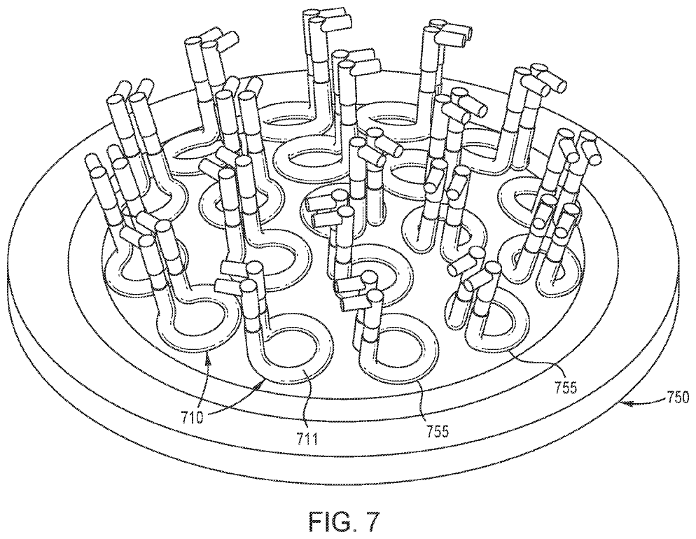

FIG. 7 is a schematic perspective view of a window 750 and a plurality of lamps 710, according to one or more embodiments.

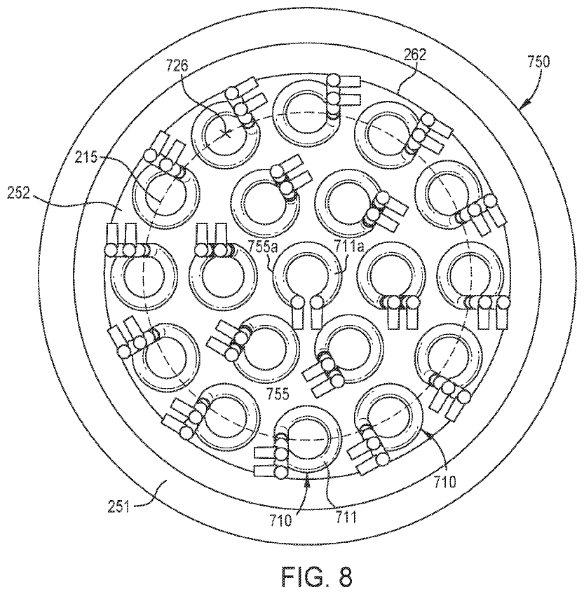

FIG. 8 is a schematic top view of the plurality of lamps 710 and the window 750 shown in FIG. 7, according to one or more embodiments.

The lamps 710 are similar to the lamps 210, 510 shown in FIGS. 1-6 and include one or more of the aspects, features, components, operations, and/or operations thereof. The window 750 is similar to the window 250 shown in FIGS. 1-6 and includes one or more of the aspects, features, components, operations, and/or operations thereof.

The window 750 includes a plurality of grooves 755. The grooves 755 and the lamps 710 disposed therein are disposed in a spaced arrangement with respect to each other. The spaced arrangement is non-concentric such that neither an inner diameter nor an outer diameter of each bulb tube 711 is within nor overlapping the inner diameter or the outer diameter of any adjacent bulb tube 711. The spaced arrangement is non-concentric such that neither an inner diameter nor an outer diameter of each groove 755 is within nor overlapping the inner diameter or the outer diameter of any adjacent groove 755. In one or more embodiments, the bulb tubes 711 are cylindrical. In one or more embodiments, cross sections of the bulb tubes 711 are arcuate (e.g., circular) in shape. The present disclosure contemplates that other shapes (e.g., rectangular shapes) may be used for the cross sections of the bulb tubes 711.

In the implementation shown in FIGS. 7 and 8, three radial locations are shown. Except for a central lamp 710a and central groove 755a, the geometric center 726 of each groove 755 and lamp 710 is aligned with the arcuate profile 215 of one of the radial locations.

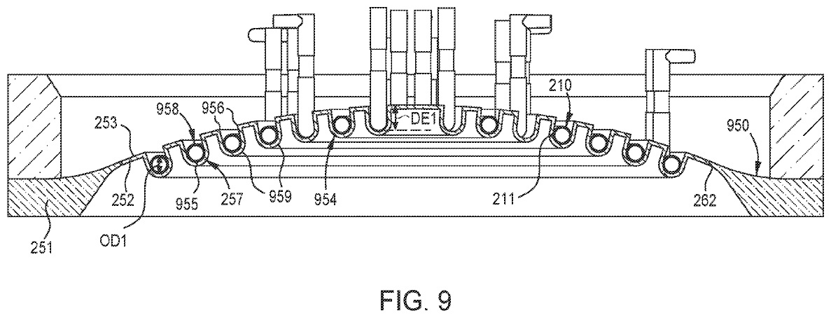

FIG. 9 is a schematic side cross-sectional view of the plurality of lamps 210 shown in FIGS. 1-4 and a window 950, according to one or more embodiments. The window 950 is similar to the window 250 shown in FIGS. 1-6 and includes one or more of the aspects, features, components, operations, and/or operations thereof.

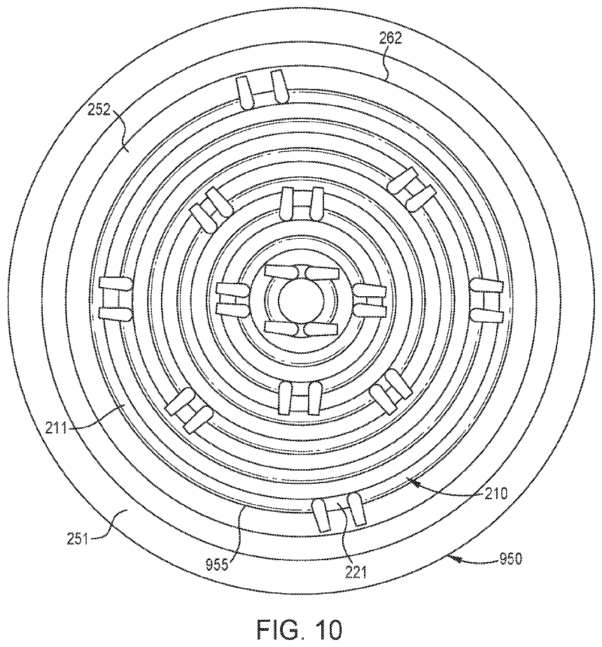

FIG. 10 is a schematic top view of the plurality of lamps 210 and the window 950 shown in FIG. 9, according to one or more embodiments.

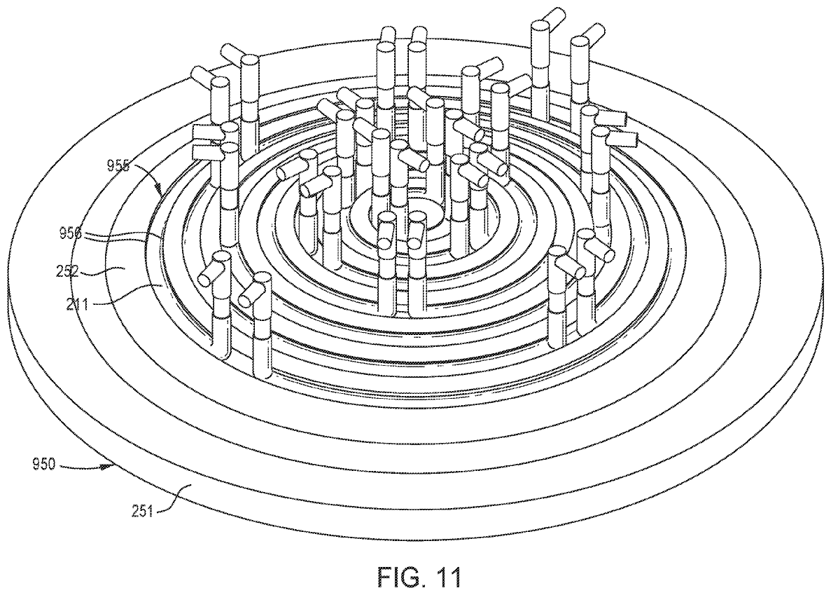

FIG. 11 is a schematic perspective view of the plurality of lamps 210 and the window 950 shown in FIG. 9, according to one or more embodiments.

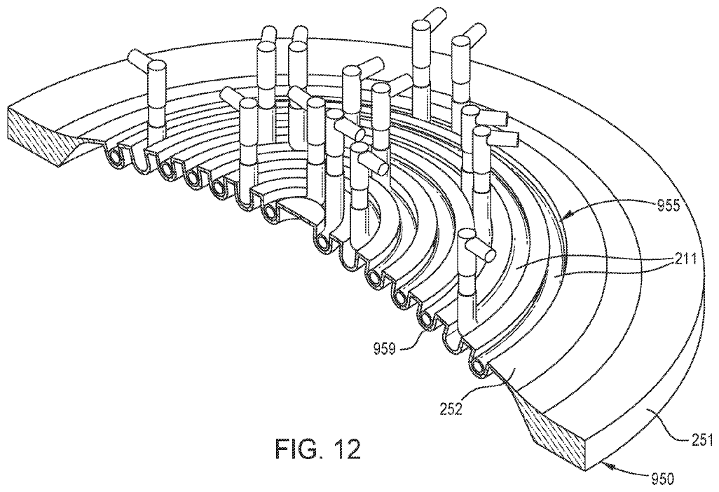

FIG. 12 is a schematic cross-sectional view of the plurality of lamps 210 and the window 950 shown in FIG. 11, according to one or more embodiments.

The window 950 includes a plurality of grooves 955, and each groove 955 includes the arcuate section 257 and a rectangular section 958 between the arcuate section 257 and the first outer face 253 such that the arcuate section 257 is recessed from the first outer face 253 at a distance from the first outer face 253. The window 950 includes a second outer face 954 that has a plurality of protrusions 959 (such as ridges) formed thereon. Corners 956 transition the first outer face 253 to each rectangular section 958. The present disclosure contemplates that the corners 956 can be tapered (e.g., chamfered) or rounded. Each groove 955 is formed at a groove depth DE1. The bulb tube 211 of each lamp 210 has an outer diameter OD1, and the groove depth DE1 is equal to or larger than the outer diameter OD1. In one or more examples, the outer diameter OD1 is about 13 mm, and the groove depth DE1 is equal to or greater than 13 mm.

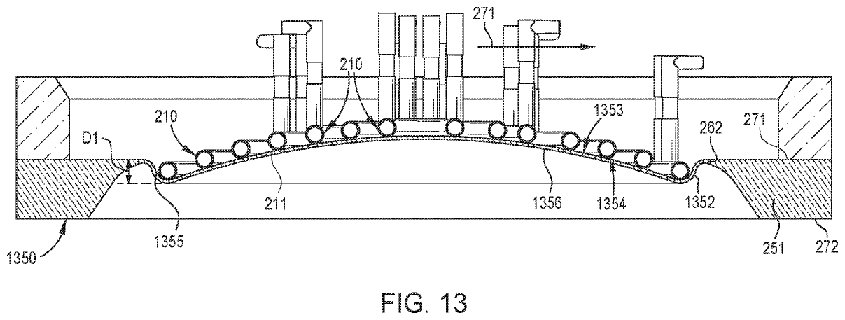

FIG. 13 is a schematic side cross-sectional view of the plurality of lamps 210 shown in FIGS. 9-12 and a window 1350, according to one or more embodiments. The window 1350 is similar to the window 250 shown in FIGS. 1-6 and includes one or more of the aspects, features, components, operations, and/or operations thereof.

An inner section 1352 of the window 1350 hangs relative to an upper surface 271 of the outer section 251 such that the inner section 1352 is aligned between the upper surface 271 and a lower surface 272 of the outer section 251. In one or more embodiments, a lowermost end of the inner section 1352 hangs below the upper surface 271 of the outer section 251 by a distance D1 that is about 0.5 inches.

The window 1350 includes a single groove 1355. The single groove 1355 is a trough that encircles the radial center 261 of the inner section 252. The single groove 1355 defines a recessed surface 1356 having a gradient that transitions toward a second outer face 1354 of the window 1350 in the direction D1 from the radial center 261 to the radial outer edge 262. The recessed surface 1356 is part of a first outer face 1353 of the window 1350.

The plurality of lamps 210 are received in the single groove 1355, and each lamp 210 of the plurality of lamps 210 rests on the recessed surface 1356.

Benefits of the present disclosure include thermal (e.g., heating) efficiency and reduced power consumption (e.g., power for heating) at increased yield and throughput, and in a manner that facilitates reduced or mitigated degradation of chamber components (such as seals). For example using a lamp module described herein (e.g., an upper lamp module including the lamps 210), it is believed that a higher processing temperature can be achieved at a lower (e.g., less than half, such as about 25%) lamp input power than other operations. As an example, larger portions of the processing volume 136 that may otherwise be at 600-800 degrees Celsius can be at the higher processing temperature that is 1,000 degrees Celsius or greater (such as about 1,200 degrees Celsius) when the lower lamp input power is used. Additionally as an example, portions of the substrate 102 (such as outer portion(s) of the substrate 102) can heat to higher temperatures (e.g., at 1,000 degrees Celsius or higher), which facilitates deposition uniformity and high growth rates. As a further example, portions of the substrate support 106 aligned under the outer portion(s) of the substrate 102 can heat to higher temperatures (e.g., at 1,400 degrees Celsius or higher).

Benefits also include enhanced temperature uniformity and deposition uniformity (such as substrate center-to-edge uniformity), enhanced device performance, product lifespans, simpler components and/or reduced numbers of components, reduced component costs, reduced chamber costs, and reduced operating costs. As an example, the lamps described herein facilitate increased lamp lifespans. As another example, windows and lamps described herein facilitate less heat loss (e.g., to chamber components) and increased percentages of the heat generated being absorbed by the substrate being processed rather than other components.

It is contemplated that aspects described herein can be combined. For example, one or more features, aspects, components, operations, and/or properties of the processing chamber 100, the window 250, the lamps 210, the lamps 510, the window 750, the lamps 710, the window 950, and/or the window 1350 can be combined. It is further contemplated that any combination(s) can achieve the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A lamp applicable for use in semiconductor manufacturing, comprising:
a bulb tube extending along at least a segment of an arcuate profile, the bulb tube defining an arcuate central opening.
a filament positioned in the arcuate central opening, the filament extending along at least the segment of the arcuate profile; and
a reflective coating formed on a first portion of an outer face of the bulb tube.

2. The lamp of claim 1, wherein the reflective coating is formed over the first portion such that a second portion of the outer face is uncoated.

3. The lamp of claim 2, wherein the reflective coating includes one or more of: gold (Au), silver, alumina, or one or more other ceramics.

4. The lamp of claim 2, wherein the reflective coating is formed over the first portion at a coating angle about the bulb tube, and the coating angle is at least 180 degrees.

5. The lamp of claim 4, wherein the coating angle is at least 210 degrees.

6. The lamp of claim 1, wherein the bulb tube extends along at least the segment of the arcuate profile to define an angular gap between a first terminal end and a second terminal end of the bulb tube.

7. The lamp of claim 6, wherein the angular gap has a gap angle that is less than 45 degrees.

8. The lamp of claim 6, further comprising:
a first extension tube disposed adjacent the first terminal end and extending to intersect the bulb tube;
a second extension tube disposed adjacent the second terminal end and extending to intersect the bulb tube;
a first electrical connector coupled to the first extension tube, the first electrical connector configured to couple to a supply line; and
a second electrical connector coupled to the second extension tube,
the second electrical connector configured to couple a ground line.

9. A window applicable for use in semiconductor manufacturing, comprising:
an outer section; and
an inner section disposed inwardly of the outer section, the inner section comprising:
a first outer face,
a second outer face opposing the first outer face, and
one or more grooves formed in the first outer face.

10. The window of claim 9, wherein the one or more grooves comprise a plurality of grooves disposed in a concentric arrangement with respect to each other.

11. The window of claim 10, further comprising a plurality of lamps received in the plurality of grooves, wherein each lamp of the plurality of lamps is disposed in an arcuate section of a respective groove of the plurality of grooves.

12. The window of claim 11, wherein a plurality of lamps are disposed in each groove of the one or more grooves.

13. The window of claim 11, wherein each respective groove of the plurality of grooves further comprises a rectangular section between the arcuate section and the first outer face such that the arcuate section is recessed from the first outer face.

14. The window of claim 10, wherein the inner section has a radial center and a radial outer edge that interfaces with the outer section, and the first outer face has a gradient that transitions toward the second outer face in a direction from the radial center to the radial outer edge.

15. The window of claim 14, wherein the inner section is transparent, and the outer section is opaque.

16. The window of claim 9, wherein the one or more grooves comprise a plurality of grooves disposed in a spaced arrangement with respect to each other.

17. The window of claim 16, further comprising a plurality of lamps received in the one or more grooves, wherein each lamp of the plurality of lamps is disposed in an arcuate section of a respective groove of the plurality of grooves.

18. The window of claim 9, wherein the one or more grooves comprise a single groove, the inner section has a radial center and a radial outer edge that interfaces with the outer section, and the single groove defines a recessed surface having a gradient that transitions toward the second outer face in a direction from the radial center to the radial outer edge.

19. The window of claim 18, wherein the window further comprises a plurality of lamps received in the single groove, wherein each lamp of the plurality of lamps rests on the recessed surface.

20. A processing chamber applicable for use in semiconductor manufacturing, comprising:
an internal volume;
a substrate support disposed in the internal volume, the substrate support comprising a support face;
a window at least partially defining a processing volume of the internal volume, the window comprising:
an outer section,
an inner section disposed inwardly of the outer section and having a radial center and a radial outer edge that interfaces with the outer section, the inner section comprising:
a first outer face facing away from the support face,
a second outer face opposing the first outer face, the second outer face facing the support face, and
one or more grooves formed in the first outer face; and
a plurality of lamps received in the one or more grooves of the window and supported by the inner section such that a distance between the lamps and the support face has a gradient that transitions toward the support face in a direction from the radial center to the radial outer edge.
